(19) United States
(12) Patent Application Publication
(10) Pub. No.: US 2007/0069157 A1
(43) Pub. Date: Mar. 29, 2007

(54) Methods and apparatus for plasma implantation with improved dopant profile

(75) Inventors: Sandeep Mehta, Beverly, MA (US); Steven R. Walther, Andover, MA (US); Naushad Variam, Marblehead, MA (US); Ukyo Jeong, Eugene, OR (US)

Correspondence Address: Mark A. Superko, Esq.;Varian Semiconductor Equipment Associates, Inc., 35 Dory Road, Gloucester, MA, 01930-2297, US

(73) Assignee: Varian Semiconductor Equipment Associates, Inc., Gloucester, MA (US)

(21) Appl. No.: 11/237,385

(22) Filed: Sep. 28, 2005

(51) Int. Cl. H01J 37/08

(52) U.S. Cl. 250/492.21

(57) ABSTRACT

Methods and apparatus for plasma ion implantation with improved dopant profiles are provided. A plasma ion implantation system includes a process chamber, a plasma source to generate a plasma in the process chamber, a platen to hold the substrate in the process chamber and a pulse source to generate implant pulses to accelerate ions from the plasma into the substrate. In one aspect, the pulse source generates implant pulses having pulse widths that are sufficiently long to limit plasma ion implantation during a transient period at the start of each implant pulse to a small fraction of the total implanted dose. In another aspect, ions are generated in a region of the process chamber near a reference potential, such as ground, and are accelerated from the region of plasma generation to the platen. Plasma generation may be enabled after the start of each implant pulse and may be disabled before the end of each implant pulse.

### FIELD OF THE INVENTION

This invention relates to systems and methods for plasma ion implantation of substrates and, more particularly, to methods and apparatus for plasma ion implantation of substrates with improved dopant profiles.

### BACKGROUND OF THE INVENTION

Ion implantation is a standard technique for introducing conductivity-altering impurities into semiconductor wafers. In a conventional beamline ion implantation system, a desired impurity material is ionized in an ion source, the ions are accelerated to form an ion beam of prescribed energy, and the ion beam is directed at the surface of the wafer. Energetic ions in the beam penetrate into the bulk of the semiconductor material and are embedded into the crystalline lattice of the semiconductor material to form a region of desired conductivity.

A well-known trend in the semiconductor industry is toward smaller, higher speed devices. In particular, both the lateral dimensions and the depths of features in semiconductor devices are decreasing. The implanted depth of the dopant material is determined, at least in part, by the energy of the ions implanted into the semiconductor wafer. Beamline ion implanters are typically designed for efficient operation at relatively high implant energies and may not function efficiently at the low energies required for shallow junction implantation.

Plasma doping systems, also known as plasma ion implantation systems, have been studied for forming shallow junctions in semiconductor wafers. In a plasma doping system, a semiconductor wafer is placed on a conductive platen, which functions as a cathode and which is located in a process chamber. An ionizable process gas containing the desired dopant material is introduced into the chamber, and a voltage pulse is applied between the platen and an anode or the chamber walls, causing formation of a plasma having a plasma sheath in the vicinity of the wafer. The applied pulse causes ions in the plasma to cross the plasma sheath and to be implanted into the wafer. The depth of implantation is related to the voltage applied between the wafer and the anode. Very low implant energies can be achieved.

In the plasma doping systems described above, the applied voltage pulse generates a plasma and accelerates positive ions from the plasma toward the wafer. In other types of plasma systems, known as plasma immersion systems, continuous or pulsed RF energy is applied to the process chamber, thus producing a continuous or pulsed plasma. At intervals, negative voltage pulses, which may be synchronized with the RF pulses, are applied between the platen and the anode, causing positive ions in the plasma to be accelerated toward the wafer.

The plasma doping system produces in the wafer being implanted a dopant profile, which may be defined as the dopant concentration as a function of depth from the surface of the wafer. It is desirable that the dopant profile have a peak at a selected implant depth, with reduced dopant concentration at the surface of the wafer. In practice plasma doping systems may exhibit surface deposition and implantation at depths less than the selected implant depth, resulting in undesired dopant profiles that are peaked at or near the surface of the wafer. Accordingly, there is a need for methods and apparatus for plasma ion implantation with improved dopant profiles.

### SUMMARY OF THE INVENTION

According to a first aspect of the invention, a plasma ion implantation system is provided. The plasma ion implantation system comprises a process chamber, a plasma source to generate a plasma in the process chamber, a platen to hold the substrate in the process chamber, and a pulse source to generate implant pulses to accelerate ions from the plasma into the substrate. The pulse source generates implant pulses having pulse widths that are sufficiently long to limit plasma ion implantation during a transient period at the start of each implant pulse to a small fraction of the total implanted dose.

According to a second aspect of the invention, a method is provided for plasma ion implantation of a substrate in a plasma ion implantation system including a process chamber. The method comprises generating a plasma in the process chamber, holding a substrate in the process chamber, and accelerating ions from the plasma into the substrate with implant pulses having pulse widths that are sufficiently long to limit plasma ion implantation during a transient period at the start of each implant pulse to a small fraction of the total implanted dose.

According to a third aspect of the invention, a plasma ion implantation system is provided. The plasma ion implantation system comprises a process chamber, a plasma source to generate a plasma in a region of the process chamber near a reference potential, a platen to hold a substrate in the process chamber, and a pulse source to generate implant pulses to accelerate ions from the region of plasma generation into the substrate.

According to a fourth aspect of the invention, a method is provided for plasma ion implantation of a substrate in a plasma ion implantation system including a process chamber. The method comprises generating a plasma in a region of the process chamber near a reference potential, holding a substrate in the process chamber, and accelerating ions with implant pulses from the region of plasma generation into the substrate.

### BRIEF DESCRIPTION OF THE DRAWINGS

For a better understanding of the present invention, reference is made to the accompanying drawings, which are incorporated herein by reference and in which:

FIG. 1 is a simplified schematic block diagram of a plasma ion implantation system;

FIG. 2 is a graph of implanted dose as a function of depth in a semiconductor wafer in accordance with an embodiment of the invention and in accordance with prior art techniques;

FIG. 3 illustrates an implant pulse in accordance with an embodiment of the invention;

FIG. 4 is a simplified schematic block diagram of a plasma ion implantation system in accordance with an embodiment of the invention;

FIG. 5 is a simplified schematic block diagram of a plasma ion implantation system in accordance with an embodiment of the invention; and

FIG. 6 illustrates relative timing of an implant pulse and a plasma pulse in accordance with an embodiment of the invention.

### DETAILED DESCRIPTION

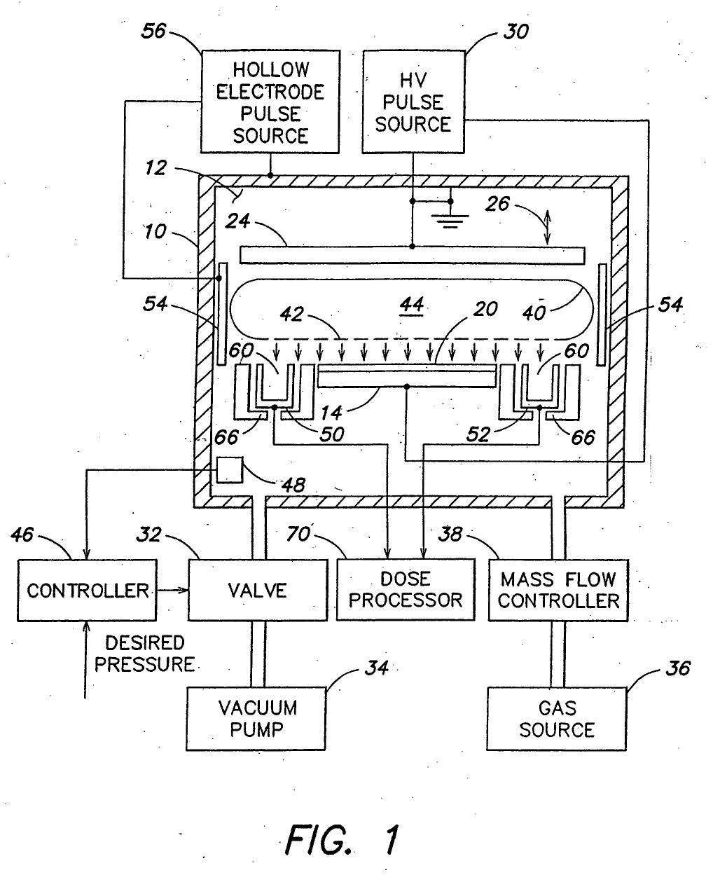

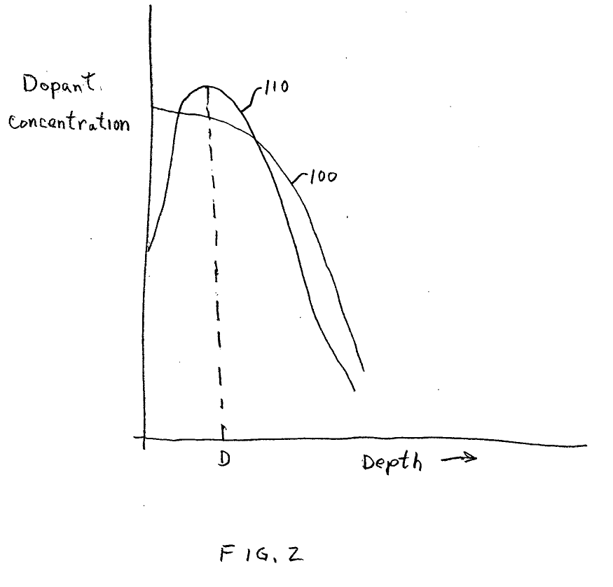

An example of a plasma ion implantation system suitable for implementation of the present invention is shown schematically in FIG. 1. Embodiments of the invention are described in connection with FIGS. 2-7. Like elements in FIGS. 1-7 have the same reference numerals.

A process chamber 10 defines an enclosed volume 12. A platen 14 positioned within chamber 10 provides a surface for holding a substrate, such as a semiconductor wafer 20. The wafer 20 may, for example, be clamped at its periphery to a flat surface of platen 14. In one embodiment, the platen has an electrically conductive surface for supporting wafer 20. In another embodiment, the platen includes conductive pins (not shown) for connection to wafer 20. In a further embodiment, the platen includes a conductive element and a dielectric layer which separates the wafer from the conductive element.

An anode 24 is positioned within chamber 10 in spaced relation to platen 14. Anode 24 may be movable in a direction, indicated by arrow 26, perpendicular to platen 14. The anode is typically connected to electrically conductive walls of chamber 10, both of which may be connected to ground. In another embodiment, platen 14 is connected to ground, and anode 24 is pulsed to a positive voltage. In further embodiments, both anode 24 and platen 14 may be biased with respect to ground.

The wafer 20 (via platen 14) and the anode 24 are connected to a high voltage pulse source 30, so that wafer 20 functions as a cathode. The pulse source 30 typically provides pulses in a range of about 20 to 20,000 volts in amplitude and a pulse repetition rate of about 100 Hz to 20 kHz. Suitable pulse widths are described below. It will be understood that these pulse parameter values are given by way of example only and that other values may be utilized within the scope of the invention. In the embodiment where the platen includes a dielectric layer, the pulses are capacitively coupled to the wafer.

The enclosed volume 12 of chamber 10 is coupled through a controllable valve 32 to a vacuum pump 34. A process gas source 36 is coupled through a mass flow controller 38 to chamber 10. A pressure sensor 48 located within chamber 10 provides a signal indicative of chamber pressure to a controller 46. The controller 46 compares the sensed chamber pressure with a desired pressure input and provides a control signal to valve 32 or mass flow controller 38. The control signal controls valve 32 or mass flow controller 38 so as to minimize the difference between the chamber pressure and the desired pressure. Vacuum pump 34, valve 32, mass flow controller 38, pressure sensor 48 and controller 46 constitute a closed loop pressure control system. The pressure is typically controlled in a range of about 1 millitorr to about 500 millitorr, but is not limited to this range. Gas source 36 supplies an ionizable gas containing a desired dopant for implantation into the workpiece. Examples of ionizable gas include BF₃, N₂, Ar, PH₃, AsH₃ and B₂H₆. Mass flow controller 38 regulates the rate at which gas is supplied to chamber 10. The configuration shown in FIG. 1 provides a continuous flow of process gas at a desired flow rate and constant pressure. The pressure and gas flow rate are preferably regulated to provide repeatable results. In another embodiment, the gas flow may be regulated using a valve controlled by controller 46 while valve 32 is kept at a fixed position. Such an arrangement is referred to as upstream pressure control. Other configurations for regulating gas pressure may be utilized.

The plasma doping system may include a hollow cathode 54 connected to a hollow cathode pulse source 56. In one embodiment, the hollow cathode 54 comprises a conductive hollow cylinder that surrounds the space between anode 24 and platen 14. The hollow cathode may be utilized in applications which require very low ion energies. In particular, hollow cathode pulse source 56 provides a pulse voltage that is sufficient to form a plasma within chamber 12, and pulse source 30 establishes a desired implant voltage. Additional details regarding the use of a hollow cathode are provided in the aforementioned U.S. Pat. No. 6,182,604, which is hereby incorporated by reference.

One or more Faraday cups may be positioned adjacent to platen 14 for measuring the ion dose implanted into wafer 20. In the embodiment of FIG. 1, Faraday cups 50, 52, etc. are equally spaced around the periphery of wafer 20. Each Faraday cup comprises a conductive enclosure having an entrance 60 facing plasma 40. Each Faraday cup is preferably positioned as close as is practical to wafer 20 and intercepts a sample of the positive ions accelerated from plasma 40 toward platen 14. In another embodiment, an annular Faraday cup is positioned around wafer 20 and platen 14.

The Faraday cups are electrically connected to a dose processor 70 or other dose monitoring circuit. Positive ions entering each Faraday cup through entrance 60 produce in the electrical circuit connected to the Faraday cup a current that is representative of ion current. The dose processor 70 may process the electrical current to determine ion dose.

The plasma ion implantation system may include a guard ring 66 that surrounds platen 14. The guard ring 66 may be biased to improve the uniformity of implanted ion distribution near the edge of wafer 20. The Faraday cups 50, 52 may be positioned within guard ring 66 near the periphery of wafer 20 and platen 14.

The plasma ion implantation system may include additional components, depending on the configuration of the system. Systems which utilize continuous or pulsed RF energy include an RF source coupled to an antenna or an induction coil. The system may include magnetic elements which provide magnetic fields that confine electrons and control plasma density and spatial distribution. The use of magnetic elements in plasma ion implantation systems is described, for example, in WO 03/049142, published 12 Jun. 2003, which is hereby incorporated by reference.

In operation, wafer 20 is positioned on platen 14. The pressure control system, mass flow controller 38 and gas source 36 produce the desired pressure and gas flow rate within chamber 10. By way of example, the chamber 10 may operate with BF₃ gas at a pressure of 10 millitorr. The pulse source 30 applies a series of high voltage pulses to platen 14, causing formation of plasma 40 in a plasma discharge region 44 between wafer 20 and anode 24. As known in the art, plasma 40 contains positive ions of the ionizable gas from gas source 36. Plasma 40 includes a plasma sheath 42 in the vicinity, typically at the surface, of wafer 20. The electric field that is present between anode 24 and platen 14 during the high voltage pulse accelerates positive ions from plasma 40 across plasma sheath 42 toward platen 14. The accelerated ions are implanted into wafer 20 to form regions of impurity material. The pulse voltage is selected to implant the positive ions to a desired depth in wafer 20. The number of pulses and the pulse duration are selected to provide a desired dose of impurity material in wafer 20. The current per pulse is a function of pulse voltage, gas pressure and species and any variable position of the electrodes. For example, the cathode-to-anode spacing may be adjusted for different voltages.

Prior art plasma ion implantation systems may produce a dose profile that is peaked at or near the wafer surface, as indicated by curve 100 in FIG. 2. A desired dose profile, as indicated by curve 110 in FIG. 2, is peaked at a specified depth, D, which corresponds to the implant energy. Surface peaked dopant profiles are less efficient than dose profiles that are peaked at a desired depth, D, for a number of reasons, including but not limited to more inactive dopant near the surface which degrades mobility, greater diffusion required for adequate activation, significantly higher dose required than a corresponding beamline implant and limited compatibility with anneal techniques which avoid diffusion. Accordingly, it is desirable to reduce the low energy component of the implanted ions which produce surface deposition and near surface implantation.

In embodiments of the invention, techniques are provided which reduce the low energy component of the implanted ions. The low energy component refers to ions at energies less than the desired implant energy. One source of the low energy component of the ions implanted into the wafer is the transient conditions at the beginning and end of each implant pulse in a pulsed plasma ion implantation system. In a pulsed ion implantation system, implant pulses, or bias pulses, are applied to the platen 14 which supports the semiconductor wafer. The implant pulses are usually negative pulses having the amplitude of the desired implant voltage. When the implant pulse applied to platen 14 switches from ground potential to the desired implant voltage, a plasma sheath at the surface of wafer 20 changes from a relatively thin plasma sheath to a thicker plasma sheath that corresponds to the applied voltage. The plasma sheath after a transient period is a region adjacent to wafer 20 that contains no charged particles except for ions crossing the sheath from the plasma into wafer 20. During a steady state condition after application of the implant pulse, ions are implanted at a more or less uniform energy from the plasma through the plasma sheath into wafer 20.

During the transient period after application of the implant pulse, the thin plasma sheath changes to a thicker plasma sheath. At the instant when the implant pulse is applied, a region above wafer 20 contains both electrons and positive ions. The electrons are quickly removed by the applied voltage, leaving the positive ions. The positive ions are attracted to the platen 14 by the applied negative voltage. However, the positive ions leave the plasma sheath region over a longer period, for example, over about 2 microseconds. The sheath, during this transient period, is known as a matrix sheath. The length of the transient period during which the matrix sheath exists depends on pulse risetime, ion mass, sheath thickness and the voltage across the sheath, and may be longer than the pulse risetime. The positive ions that are accelerated from the sheath region to the wafer 20 during the transient period may not be accelerated by the full voltage of the implant pulse applied to platen 14. The actual acceleration of these ions depends on their positions in the sheath region when the implant pulse is applied. The ions in the sheath region are accelerated by less than the full voltage of the implant pulse and, thus, are implanted nearer to the surface of the wafer than the desired implant depth, D.

A matrix sheath is not associated with the falltime of the implant pulse. However, a transient period during which ions are not accelerated by the full voltage of the implant pulse is associated with the end of each implant pulse. The transient period at the end of each implant pulse may correspond to the falltime of the implant pulse.

According to an embodiment of the invention, the effect of the low energy ion component that results from the transient period at the beginning of each implant pulse and the falltime at the end of each implant pulse is reduced by utilizing relatively long implant pulses. Current practice typically utilizes implant pulses of about 1 to 50 microseconds. For an implant pulse having a pulse width of 10 microseconds, a transient period of 2 microseconds at the beginning of each pulse has a significant contribution to the low energy component of the implant. However, the transient period remains fixed in length as the pulse width is varied, and the transient period makes a negligible contribution to the overall implant in the case of a relatively long implant pulse, such as 500 microseconds, for example.

Implant pulse widths in a range of greater than 100 microseconds to 5 milliseconds may be utilized to improve the dose profile produced by plasma ion implantation of semiconductor wafers. More preferably, implant pulse widths in a range of greater than 200 microseconds to 5 milliseconds may be utilized. The maximum pulse width may be limited by charging considerations in the case of plasma ion implantation of semiconductor wafers. In other applications, the maximum pulse width may not be limited.

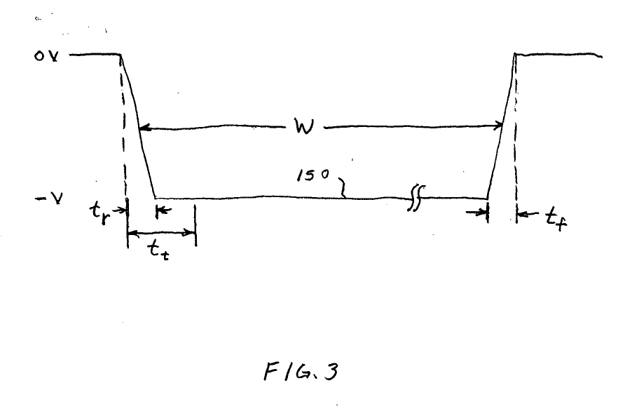

The pulse width of the implant pulse should be much greater, preferably 100 or more times greater, than the sum of the transient period at the start of the implant pulse and the falltime at the end of the implant pulse. Thus for an example of a transient period of 2 microseconds and a falltime of 1 microsecond, an implant pulse of 300 microseconds or greater is used. This approach reduces the number of ions implanted at less than full energy to less than 1% of the total implanted dose. Thus, referring to FIG. 3, implant pulse 150 has a width, W, that is much greater than the transient period tₜ plus the falltime t_{f} of the implant pulse. As shown, the transient period tₜ may be greater than the risetime tᵣ of the implant pulse.

According to additional embodiments of the invention, the plasma ion implantation system is configured such that the plasma is generated in a region of the process chamber that is near ground potential or other reference potential and is accelerated to the wafer for implantation. This configuration ensures that the ions in the plasma are accelerated from near ground potential to the full energy produced by the implant pulse. As a result, the number of ions implanted at less than full energy is reduced in comparison with prior art configurations. A further feature of these embodiments is that the plasma generator can be enabled or turned on after the implant pulse reaches full voltage and can be disabled or turned off before the implant pulse ends. This further reduces the number of ions accelerated at less than full energy.

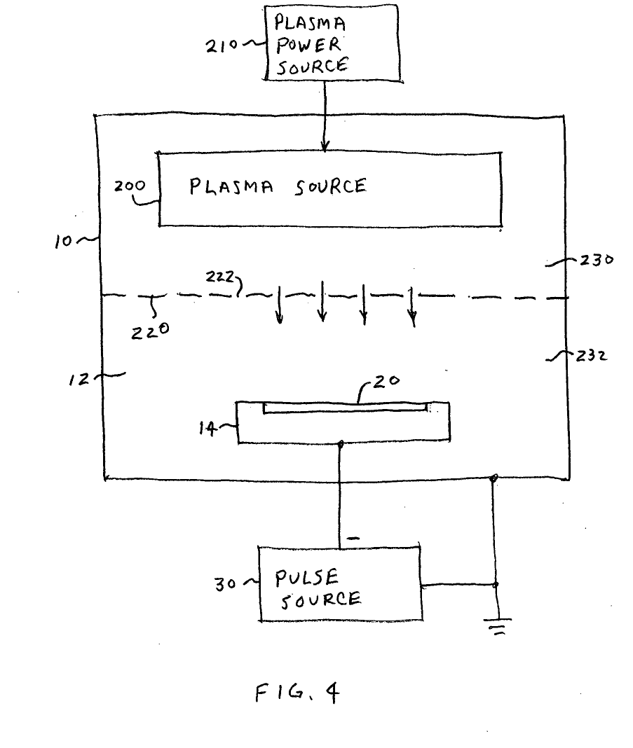

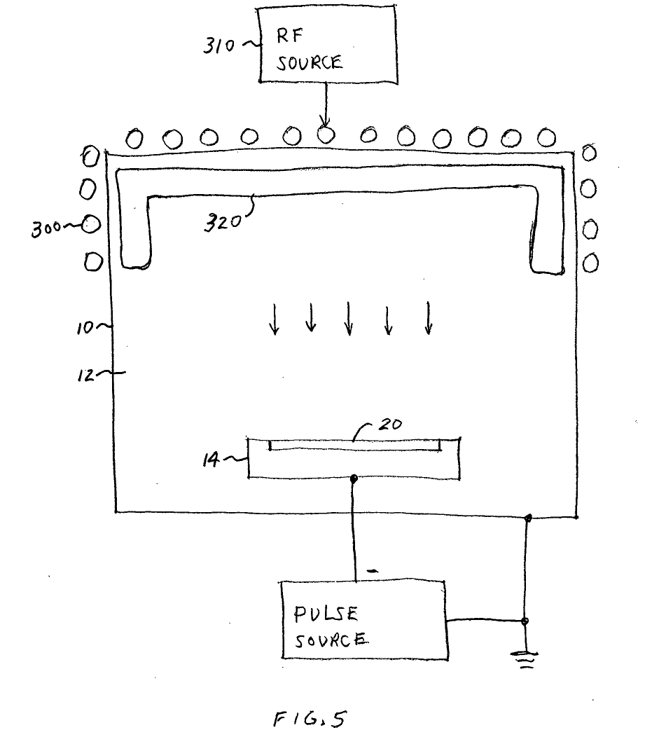

Simplified schematic block diagrams of plasma ion implantation systems in accordance with embodiments of the invention are shown in FIGS. 4 and 5. In FIGS. 1, 4, and 5, like elements have the same reference numerals. System components such as gas source 36, mass flow controller 38, valve 32, vacuum pump 34, controller 46, pressure sensor 48, Faraday cups 50, 52, and dose processor 70 are omitted from FIGS. 4 and 5 for simplicity of illustration.

As shown in FIG. 4, process chamber 10 defines enclosed volume 12. Platen 14 positioned within chamber 10 provides a surface for holding semiconductor wafer 20. Platen 14 is connected to pulse source 30, and process chamber 10 is connected to ground. Platen 14 functions as a cathode, and process chamber 10 functions as an anode. Pulse source 30 applies negative implant pulses to platen 14. The implant pulses may have the amplitudes and pulse repetition rates described above and may have pulse widths in a range of 1 microsecond to 5 milliseconds for plasma ion implantation of semiconductor wafers.

A plasma source 200 is positioned within chamber 10 and is spaced from platen 14. Plasma source 20 may be energized by a plasma power source 210. A plasma may be generated by any suitable technique, including but not limited to RF, microwave, glow discharge and the like. An electrically conductive grid 220 is positioned in chamber 10 between plasma source 200 and platen 14. Grid 220 may be electrically connected to chamber 10 and thus is at ground potential or other reference potential. Grid 220 defines a first region 230 of chamber 10 that contains plasma source 200 and a second region 232 of chamber 10 that contains platen 14. Grid 220 is provided with openings 222 so that a plasma generated by plasma source 200 may move from region 230 to region 232.

The plasma ion implantation system of FIG. 4 ensures that the plasma is generated in a region near zero potential. Ions in the plasma are accelerated from the plasma to platen 14 by the implant pulse applied by pulse source 30. Since the ions are accelerated from near zero potential by the implant pulse, the ions are accelerated to the full energy produced by the implant pulse. As a result, the low energy component of the implanted ions is limited.

In the embodiment of FIG. 5, an RF coil 300 is positioned outside chamber 10 at the opposite end of chamber 10 from platen 14. RF coil 300 is coupled to an RF source 310. When RF source 310 is energized, a plasma is created within chamber 10 in a region 320 near RF coil 300. The region 320 of ion creation is near the wall of chamber 10 and is therefore near zero potential. As in the case of FIG. 4, ions generated in region 320 are accelerated by the implant pulse applied to platen 14 by pulse source 30. Since the ions begin near zero potential, they are accelerated through the full voltage of the implant pulse and are implanted at the desired energy. As a result, the low energy component of the implanted ions is limited.

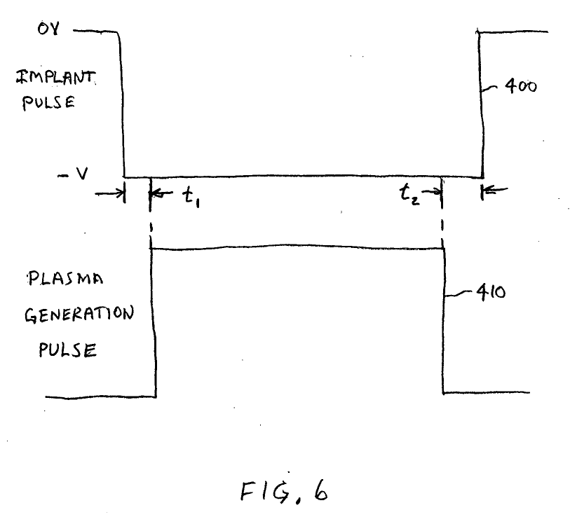

According to a further aspect of the invention, the low energy component of the implanted ions may be further reduced by controlling the timing of the plasma generation pulse relative to the implant pulse. An implant pulse 400 and a plasma generation pulse 410 are shown schematically in FIG. 6. As shown, the start of plasma generation pulse 410 is delayed with respect to the start of implant pulse 400 by a time t₁. In addition, plasma generation pulse 410 ends before implant pulse 400. Thus, the end of implant pulse 400 is delayed by a time t₂ relative to the end of plasma generation pulse 410. In the embodiments of FIGS. 4 and 5, this approach ensures that ions are accelerated through the full potential of the implant pulse from a region near zero potential into wafer 20. Transient periods at the beginning and end of implant pulse 400 are avoided, because a plasma is not present in chamber 10 at the beginning and end of implant pulse 400.

Having described several embodiments and an example of the invention in detail, various modifications and improvements will readily occur to those skilled in the art. Such modifications and improvements are intended to be within the spirit and the scope of the invention. Furthermore, those skilled in the art would readily appreciate that all parameters listed herein are meant to be exemplary and that actual parameters will depend upon the specific application for which the system of the present invention is used. Accordingly, the foregoing description is by way of example only and is not intended as limiting. The invention is limited only as defined by the following claims and their equivalents.

What is claimed is:

1. A plasma ion implantation system comprising:
a process chamber;
a plasma source to generate a plasma in the process chamber;
a platen to hold a substrate in the process chamber; and
a pulse source to generate implant pulses to accelerate ions from the plasma into the substrate, the pulse source generating implant pulses having pulse widths that are sufficiently long to limit plasma ion implantation during a transient period at the start of each implant pulse to a small fraction of the total implanted dose.

2. A plasma ion implantation system as defined in claim 1, wherein the pulse source generates implant pulses having pulse widths in a range of greater than 100 microseconds to 5 milliseconds.

3. A plasma ion implantation system as defined in claim 1, wherein the pulse source generates implant pulses having pulse widths of at least 100 times a plasma sheath formation time.

4. A plasma ion implantation system as defined in claim 1, wherein the pulse source is configured to generate implant pulses having pulse widths greater than about 100 microseconds.

5. A plasma ion implantation system as defined in claim 1, wherein the pulse source is configured to generate implant pulses having pulse widths of at least 100 times the transient period at the start of each implant pulse.

6. A plasma ion implantation system as defined in claim 1, further comprising an anode spaced from the platen, wherein the implant pulses are applied between the anode and the platen.

7. A method for plasma ion implantation of a substrate in a plasma ion implantation system including a process chamber, comprising:
generating a plasma in the process chamber;
holding a substrate in the process chamber; and
accelerating ions from the plasma into the substrate with implant pulses having pulse widths that are sufficiently long to limit plasma ion implantation during a transient period at the start of each implant pulse to a small fraction of the total implanted dose.

8. A method as defined in claim 7, comprising accelerating ions with implant pulses having pulse widths in a range of greater than 100 microseconds to 5 milliseconds.

9. A method as defined in claim 7, comprising accelerating ions with implant pulses having pulse widths of at least 100 times a plasma sheath formation time.

10. A method as defined in claim 7, wherein accelerating ions comprises applying the implant pulses between an anode in the process chamber and a platen that holds the substrate.

11. A plasma ion implantation system comprising:
a process chamber;
a plasma source to generate a plasma in a region of the process chamber near a reference potential;
a platen to hold a substrate in the process chamber; and
a pulse source to generate implant pulses to accelerate ions from the region of plasma generation into the substrate.

12. A plasma ion implantation system as defined in claim 11, further comprising a controller to enable the plasma source after the start of each of the implant pulses.

13. A plasma ion implantation system as defined in claim 12, wherein the controller is configured to disable the plasma source before the end of each of the implant pulses.

14. A plasma ion implantation system as defined in claim 11, further comprising a grid positioned in the process chamber between the plasma source and the platen, wherein the grid is coupled to the reference potential.

15. A plasma ion implantation system as defined in claim 11, wherein the region of plasma generation is near a wall of the process chamber.

16. A plasma ion implantation system as defined in claim 11, wherein the plasma source includes an RF plasma source.

17. A plasma ion implantation system as defined in claim 11, wherein the plasma source generates the plasma in a region near ground potential.

18. A method for plasma ion implantation of a substrate in a plasma ion implantation system including a process chamber, comprising:
generating a plasma in a region of the process chamber near a reference potential;
holding a substrate in the process chamber; and
accelerating ions with implant pulses from the region of plasma generation into the substrate.

19. A method as defined in claim 18, further comprising enabling generation of the plasma after the start of each of the implant pulses.

20. A method as defined in claim 19, further comprising disabling generation of the plasma before the end of each of the implant pulses.

21. A method as defined in claim 18, wherein generating a plasma and holding a substrate are performed on opposite sides of a grid connected to the reference potential.

22. A method as defined in claim 18, wherein generating a plasma comprises generating a plasma near a wall of the process chamber.

23. A method as defined in claim 18, wherein generating a plasma and holding a substrate are performed at spaced apart locations in the process chamber.
